(19) United States
(12) Patent Application Publication
(10) Pub. No.: US 2024/0154031 A1
(43) Pub. Date: May 9, 2024

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kanagawa (JP)

(72) Inventors: Masaki MIYAZATO, Matsumoto-city (JP); Mina OHSE, Matsumoto-city (JP); Yohei KAGOYAMA, Matsumoto-city (JP)

(21) Appl. No.: 18/473,277

(22) Filed: Sep. 25, 2023

(30) Foreign Application Priority Data
Nov. 4, 2022 (JP) 2022-177471

(51) Int. Cl. H01L 29/78; H01L 21/04; H01L 23/544; H01L 29/06; H01L 29/16; H01L 29/66

(52) U.S. Cl. CPC H01L 29/7811; H01L 21/046; H01L 23/544; H01L 29/0623; H01L 29/0696; H01L 29/1608; H01L 29/66068; H01L 29/7813; H01L 2223/54426

(57) ABSTRACT

Provided is a silicon carbide semiconductor device which includes a semiconductor substrate made of silicon carbide and having an epitaxial region on a front surface. The silicon carbide semiconductor device includes: an active portion which is provided on the semiconductor substrate; a pressure resistant structure portion which is provided on an outer periphery of the active portion; and an element isolation portion which is provided on an outer periphery of the pressure resistant structure portion. The element isolation portion includes an extension prevention portion which is provided to elongate along each of two opposing end sides on an upper surface of the epitaxial region and prevents extension of interface dislocation of the semiconductor substrate.

The contents of the following patent application(s) are incorporated herein by reference:
NO. 2022-177471 filed in JP on Nov. 4, 2022

### BACKGROUND

### 1. Technical Field

The present invention relates to a silicon carbide semiconductor device and a method of manufacturing the silicon carbide semiconductor device.

### 2. Related Art

Patent Document 1 describes “a silicon carbide semiconductor device and a method of manufacturing the same capable of reducing recombination of carriers at an element end part and suppressing increase in forward voltage”.

### CITATION LIST

### Patent Document

Patent Document 1: Japanese Patent Application Publication No. 2021-15880

### BRIEF DESCRIPTION OF THE DRAWINGS

FIG. 1A illustrates an example of a top view of a silicon carbide semiconductor device 100.

FIG. 1B illustrates an example of an enlarged view of a PQRS region of the silicon carbide semiconductor device 100 illustrated in FIG. 1A.

FIG. 1C illustrates an example of an upper surface of a silicon carbide semiconductor chip 100a.

FIG. 2 illustrates an example of a cross section of an active portion 110.

FIG. 3 illustrates an example of an A-A′ cross section of the silicon carbide semiconductor device 100 illustrated in FIG. 1B.

FIG. 4A illustrates an example of a B-B′ cross section of the silicon carbide semiconductor device 100 illustrated in FIG. 1B.

FIG. 4B illustrates a modification of the B-B′ cross section of the silicon carbide semiconductor device 100 illustrated in FIG. 1B.

FIG. 4C illustrates a modification of the B-B′ cross section of the silicon carbide semiconductor device 100 illustrated in FIG. 1B.

FIG. 5A illustrates a top view of a modification of the silicon carbide semiconductor device 100.

FIG. 5B illustrates an example of an enlarged view of a PQRS region of the silicon carbide semiconductor device 100 illustrated in FIG. 5A.

FIG. 5C illustrates a top view of a modification of a silicon carbide semiconductor chip 100a.

FIG. 6A illustrates an example of a flowchart of a manufacturing process of the silicon carbide semiconductor device 100.

FIG. 6B illustrates a modification of the flowchart of the manufacturing process of the silicon carbide semiconductor device 100.

FIG. 6C illustrates a modification of the flowchart of the manufacturing process of the silicon carbide semiconductor device 100.

FIG. 6D illustrates a modification of the flowchart of the manufacturing process of the silicon carbide semiconductor device 100.

FIG. 7 illustrates an example of a forming process of an interface dislocation 76.

FIG. 8A illustrates an example of a process of preventing extension of the interface dislocation 76 in the silicon carbide semiconductor device 100.

FIG. 8B illustrates an example of a forming process of the interface dislocation 76 in a silicon carbide semiconductor device according to a comparative example.

### DESCRIPTION OF EXEMPLARY EMBODIMENTS

Hereinafter, embodiments of the present invention will be described, but the embodiments do not limit the invention according to the claims. In addition, not all of the combinations of features described in the embodiments are essential to the solution of the invention.

In the present specification, one side in a direction parallel to a depth direction of a semiconductor substrate is referred to as an “upper” side, and the other side is referred to as a “lower” side. One surface of two principal surfaces of a substrate, a layer or other member is referred to as an upper surface, and the other surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described using orthogonal coordinate axes of an X axis, a Y axis, and a Z axis. In this specification, a surface parallel to the upper surface of a semiconductor substrate is defined as an X-Y surface, and the depth direction of the semiconductor substrate is defined as the Z axis.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

In the present specification, in a layer or a region specified with N or P, electrons or holes are meant to be majority carriers, respectively. Also, ‘+’ and ‘−’ attached on ‘N’ and ‘P’ respectively mean that the higher doping concentration and the lower doping concentration than the layer or region to which it is not attached.

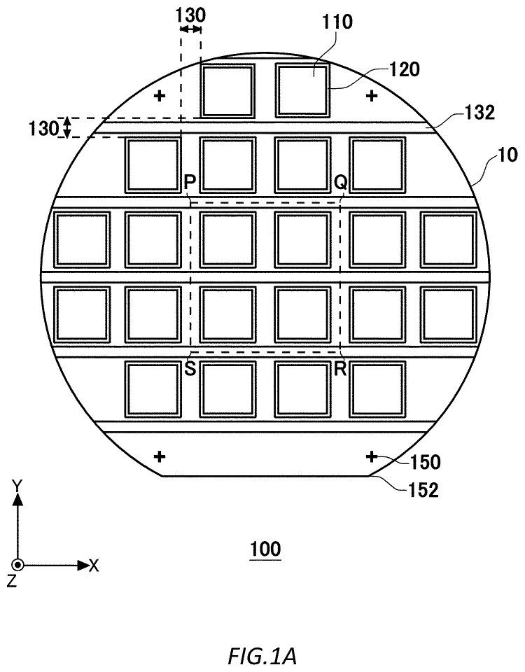

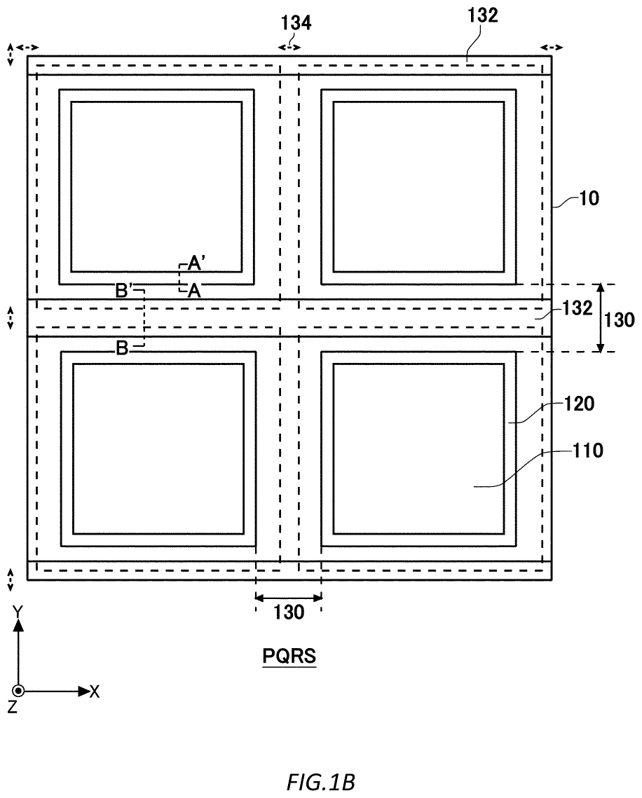

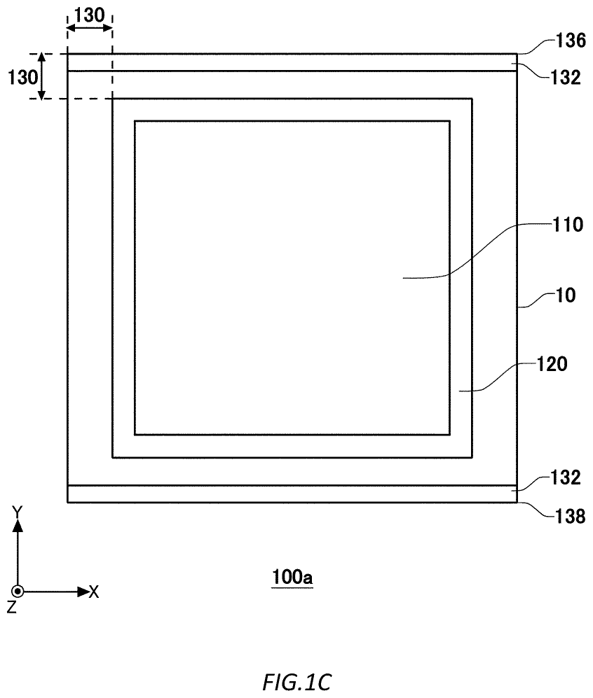

FIG. 1A illustrates an example of an upper surface of a silicon carbide semiconductor device 100. The silicon carbide semiconductor device 100 includes a semiconductor substrate 10, and includes an active portion 110, a pressure resistant structure portion 120, an element isolation portion 130, and an extension prevention portion 132 on the semiconductor substrate 10. The silicon carbide semiconductor device 100 may include an alignment mark 150 and an orientation flat 152 on the semiconductor substrate 10.

The semiconductor substrate 10 is made of silicon carbide. The semiconductor substrate 10 may have an epitaxial region 20 on a front surface 11 of the semiconductor substrate 10. The front surface 11 and the epitaxial region 20 of the semiconductor substrate 10 will be described later. The front surface 11 and the epitaxial region 20 of the semiconductor substrate 10 are not illustrated in FIG. 1A. As an example, the crystal structure of the semiconductor substrate 10 is 4H—SiC. In FIG. 1A, an X axis may be a (11-20) direction of the semiconductor substrate 10 made of silicon carbide, a Y axis may be a (1-100) direction of the semiconductor substrate 10, and a Z axis may be a (000-1) direction of the semiconductor substrate 10.

The active portion 110 is provided on the semiconductor substrate 10. The active portion 110 may be a region through which main current flows during operation of the silicon carbide semiconductor device 100. As an example, the active portion 110 has an insulated gate field effect transistor (MOSFET) structure, but is not limited thereto. The silicon carbide semiconductor device 100 of this example has 22 active portions 110, but the number of the active portions 110 provided on the silicon carbide semiconductor device 100 in a wafer state may be 21 or less or 23 or more. The number of the active portions 110 provided on the silicon carbide semiconductor device 100 in the wafer state may be appropriately designed on the basis of a chip size or the like for singulating the silicon carbide semiconductor device 100 in the wafer state.

The pressure resistant structure portion 120 is provided on the outer periphery of the active portion 110 on the semiconductor substrate 10. The pressure resistant structure portion 120 may relax an electric field concentration at the upper surface side of the semiconductor substrate 10. As an example, the pressure resistant structure portion 120 has a Junction Termination Extension (JTE) structure. As another example, the pressure resistant structure portion 120 may have a guard ring, a field plate, a RESURF, and a combination structure thereof.

The element isolation portion 130 is provided on the outer periphery of the pressure resistant structure portion 120 on the semiconductor substrate 10. The element isolation portion 130 may be a region that isolates each of the active portions 110 and the pressure resistant structure portions 120 provided on respective chips obtained when the silicon carbide semiconductor device 100 in the wafer state is singulated. That is, as illustrated in FIG. 1A, the element isolation portion 130 may be a region that separates the pressure resistant structure portions 120 adjacent in an X axis direction, or may be a region that separates the pressure resistant structure portions 120 adjacent in a Y axis direction. Alternatively, the element isolation portion 130 may be a region other than the region where the active portion 110 and the pressure resistant structure portion 120 are provided on the semiconductor substrate 10.

A boundary between the pressure resistant structure portion 120 and the element isolation portion 130 may be defined by an end portion of the structure of the pressure resistant structure portion 120. That is, in the structure of the pressure resistant structure portion 120, the end portion of the structure provided on the outermost side with the active portion 110 as a center may be set as the boundary between the pressure resistant structure portion 120 and the element isolation portion 130. Details of the structure of the pressure resistant structure portion 120 and the boundary between the pressure resistant structure portion 120 and the element isolation portion 130 will be described later.

The element isolation portion 130 has the extension prevention portion 132 that prevents extension of an interface dislocation of the semiconductor substrate 10. The extension prevention portion 132 of this example is provided in parallel to the X axis direction. The extension prevention portion 132 may be provided in parallel to the (11-20) direction of the semiconductor substrate 10. The extension prevention portions 132 may be provided in all regions where the pressure resistant structure portions 120 adjacent to each other in the Y axis direction are separated from each other. On the silicon carbide semiconductor device 100 of this example, at most five active portions 110 and at most five pressure resistant structure portions 120 are provided in the Y axis direction, and thus at least four extension prevention portions 132 are provided. The extension prevention portion 132 may be provided further outside the active portion 110 and the pressure resistant structure portion 120 positioned on the outermost side. On the silicon carbide semiconductor device 100 of this example, the extension prevention portion 132 is provided further outside the active portion 110 and the pressure resistant structure portion 120 positioned on the outermost side, and thus six extension prevention portions 132 are provided.

By providing the extension prevention portion 132 in the (11-20) direction of the semiconductor substrate 10, it is possible to prevent the extension of the interface dislocation occurring in the middle of the manufacturing process of the silicon carbide semiconductor device 100. The interface dislocation occurring in the middle of the manufacturing process of the silicon carbide semiconductor device 100 extends in the (1-100) direction of the semiconductor substrate 10. The extension prevention portion 132 is provided in the (11-20) direction of the semiconductor substrate 10 so that the extension of the interface dislocation is stopped by the extension prevention portion 132 even when the interface dislocation occurs in the middle of the manufacturing process of the silicon carbide semiconductor device 100, and thus the number of silicon carbide semiconductor chips that become unusable due to the extension of the interface dislocation can be reduced. Details of a forming process of the interface dislocation in the middle of the manufacturing process of the silicon carbide semiconductor device 100 will be described later.

The alignment mark 150 is a mark used for alignment in the manufacturing process of the silicon carbide semiconductor device 100. The alignment mark 150 can be formed by a common method used by persons skilled in the art. The alignment marks 150 of this example are provided at four locations on the semiconductor substrate 10, but the present invention is not limited thereto.

The orientation flat 152 is a flat surface provided on the outer periphery of the wafer to facilitate determination and/or alignment of the crystal orientation of the semiconductor substrate 10. As an example, the orientation flat 152 is provided in parallel with the (11-20) direction of the semiconductor substrate 10. Another orientation flat parallel to the (1-100) direction of the semiconductor substrate 10 may be further provided.

The silicon carbide semiconductor device 100 may be a power semiconductor device that controls a high voltage and/or a large current. As an example, the silicon carbide semiconductor device 100 is a MOSFET. The silicon carbide semiconductor device 100 may be a Pin diode or an IGBT. The silicon carbide semiconductor device 100 may be in the wafer state or in the singulated chip state.

FIG. 1B illustrates an example of an enlarged view of a PQRS region of the silicon carbide semiconductor device 100 illustrated in FIG. 1A. A double-headed arrow indicated by a broken line represents a dicing region 134 for singulating the silicon carbide semiconductor device 100 in the wafer state.

The dicing region 134 elongating in the X axis direction which is the elongation direction of the extension prevention portion 132 may be included in the extension prevention portion 132. A width of the extension prevention portion 132 may be larger than a width of the dicing region 134 elongating in the elongation direction of the extension prevention portion 132, and both ends of the dicing region 134 may be inside both ends of the extension prevention portion 132. That is, in the elongation direction of the extension prevention portion 132, the silicon carbide semiconductor device 100 may be singulated by dicing at least a part of the extension prevention portion 132.

A width of the dicing region 134 elongating in the Y axis direction which is a direction perpendicular to the elongation direction of the extension prevention portion 132 is not particularly limited. As an example, the width of the dicing region 134 elongating in the direction perpendicular to the elongation direction of the extension prevention portion 132 may be substantially the same as the width of the dicing region 134 elongating in the elongation direction of the extension prevention portion 132.

FIG. 1C illustrates an example of a top view of a silicon carbide semiconductor chip 100a. The silicon carbide semiconductor chip 100a may be the silicon carbide semiconductor device 100 in the singulated state. The silicon carbide semiconductor chip 100a has the semiconductor substrate 10, and includes the active portion 110, the pressure resistant structure portion 120, the element isolation portion 130, and the extension prevention portion 132 on the semiconductor substrate 10.

The extension prevention portion 132 is provided to elongate along each of two opposing end sides. That is, the extension prevention portion 132 is provided to elongate along each of a first end side 136 of the silicon carbide semiconductor chip 100a and a second end side 138 opposing the first end side 136. The extension prevention portion 132 may be provided to elongate from one end to the other end of the first end side 136, or may be provided to elongate from one end to the other end of the second end side 138. The elongation direction of the extension prevention portion 132 may be the (11-20) direction of the semiconductor substrate 10.

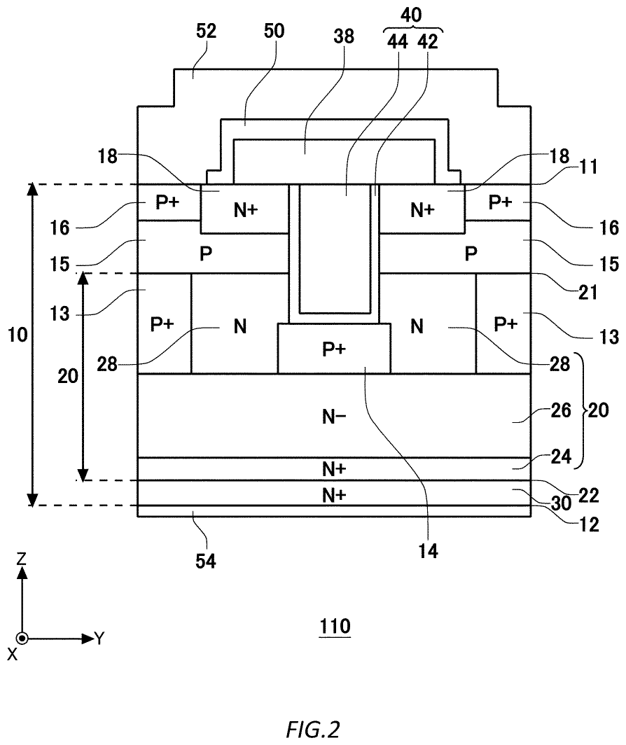

FIG. 2 illustrates an example of a cross section of the active portion 110. The active portion 110 has a first high concentration base region 13, a second high concentration base region 14, a base region 15, a contact region 16, a source region 18, an epitaxial region 20, a basal region 30, an insulating film 38, a gate trench portion 40, a barrier metal 50, a source electrode 52, and a drain electrode 54. The first high concentration base region 13, the second high concentration base region 14, the base region 15, the contact region 16, the source region 18, the epitaxial region 20, and the basal region 30 are provided inside the semiconductor substrate 10.

The active portion 110 of this example has a trench type MOSFET structure, but is not limited thereto. The active portion 110 may have a Pin diode structure or an IGBT structure. The active portion 110 may repeatedly have the MOSFET structure illustrated in FIG. 2. That is, the active portion 110 may have a structure in which the MOSFET structure illustrated in FIG. 2 is repeatedly provided at constant intervals in the Y axis direction, for example.

The basal region 30 is a first conductivity type of region provided on a back surface 12 of the semiconductor substrate 10. The basal region 30 is, for example, of N+ type. The basal region 30 may be a silicon carbide substrate made of N+ type silicon carbide.

The epitaxial region 20 includes a buffer region 24, a first drift region 26, and a second drift region 28. The epitaxial region 20 may be provided by epitaxially growing silicon carbide on the upper side of the basal region 30. A lower surface 22 of the epitaxial region 20 may be provided in contact with the upper surface of the basal region 30.

The buffer region 24 is a first conductivity type of region provided on the upper side of the basal region 30. The buffer region 24 is, for example, of N+ type. The buffer region 24 may be provided by epitaxially growing silicon carbide while doping an N type dopant. The N type dopant is, for example, a nitrogen atom.

The first drift region 26 is a first conductivity type of region provided on the upper side of the buffer region 24. The first drift region 26 is, for example, of N− type. The first drift region 26 may be provided by epitaxially growing silicon carbide while doping an N type dopant. The N type dopant is, for example, a nitrogen atom. The doping concentration of the first drift region 26 may be lower than the doping concentration of the buffer region 24.

The second drift region 28 is a first conductivity type of region provided on the upper side of the first drift region 26. The second drift region 28 is, for example, of N type. The second drift region 28 may be provided by epitaxially growing silicon carbide while doping an N type dopant. The N type dopant is, for example, a nitrogen atom. As another example, the second drift region 28 may be formed by implanting an N type dopant after being formed at the same concentration as the doping concentration of the first drift region 26. The doping concentration of the second drift region 28 may be higher than the doping concentration of the first drift region 26, or may be lower than the doping concentration of the buffer region 24.

The first high concentration base region 13 is a second conductivity type of region provided on the upper surface 21 side of the epitaxial region 20. The first high concentration base region 13 is, for example, of P+ type. The first high concentration base region 13 may be provided by forming the second drift region 28 on the entire upper surface of the first drift region 26 and then implanting a P type dopant by using an oxide film having a desired opening as a mask. The P type dopant is, for example, an aluminum atom.

The second high concentration base region 14 is a second conductivity type of region provided on the upper side of the first drift region 26. The second high concentration base region 14 is, for example, of P type. The second high concentration base region 14 may be provided by forming the second drift region 28 on the entire upper surface of the first drift region 26 and then implanting a P type dopant by using an oxide film having a desired opening as a mask, and may be etched in the forming process of the gate trench portion 40 described later. The P type dopant is, for example, an aluminum atom. As another example, the second high concentration base region 14 may be provided by forming the second drift region 28 up to a desired height on the entire upper surface of the first drift region 26, and then implanting a P type dopant by using an oxide film having a desired opening as a mask, and then the second drift region 28 may be further formed on the upper side of the second high concentration base region 14.

The base region 15 is a second conductivity type of region provided on the upper side of the epitaxial region 20. The base region 15 is, for example, of P type. The base region 15 may be provided by epitaxially growing silicon carbide on the upper side of the epitaxial region 20 while doping a P type dopant. The P type dopant is, for example, an aluminum atom.

The contact region 16 is a second conductivity type of region provided on the upper side of the base region 15. The contact region 16 is, for example, of P+ type. The contact region 16 may be provided by using an oxide film having a desired opening as a mask and implanting a P type dopant into a part of the upper surface side of the base region 15. The P type dopant is, for example, an aluminum atom.

The source region 18 is a first conductivity type of region provided on the upper side of the base region 15. The source region 18 is, for example, of N+ type. The source region 18 may be provided by using an oxide film having a desired opening as a mask and implanting an N type dopant into a part of the upper surface side of the base region 15. The N type dopant is, for example, a nitrogen atom. As another example, the source region 18 may be provided by epitaxially growing silicon carbide on the upper side of the base region 15 while doping an N type dopant.

The gate trench portion 40 is provided on the front surface 11 of the semiconductor substrate 10. The gate trench portion 40 may be provided to penetrate the base region 15 and reach the second drift region 28. A configuration in which the gate trench portion 40 penetrates the base region 15 is not limited to that manufactured in the order of forming the base region 15 and then forming the gate trench portion 40. A configuration in which the base region 15 is formed on the sidewall of the gate trench portion 40 after the gate trench portion 40 is formed is also included in the configuration in which the gate trench portion 40 penetrates the base region 15. The bottom of the gate trench portion 40 may be provided in contact with the second high concentration base region 14.

The gate trench portion 40 has a gate insulating film 42 and a gate conductive portion 44. The gate insulating film 42 is formed to cover the inner wall of the gate trench portion 40. The gate insulating film 42 may be formed by oxidizing the semiconductor on the inner wall of the gate trench portion 40. Inside the gate trench portion 40, the gate conductive portion 44 is formed inside the gate insulating film 42. The gate insulating film 42 insulates the gate conductive portion 44 from the semiconductor substrate 10. The gate conductive portion 44 is formed of a conductive material such as polysilicon. The gate trench portion 40 is covered with the insulating film 38 on the front surface 11 of the semiconductor substrate 10.

The barrier metal 50 is provided so as to cover the insulating film 38. The material of the barrier metal 50 may contain titanium or titanium nitride.

The source electrode 52 is provided on the upper side of the semiconductor substrate 10 with the insulating film 38 interposed therebetween. The source electrode 52 is formed of a material containing metal. At least a partial region of the source electrode 52 may be formed of metal such as aluminum (Al) or a metal alloy such as an aluminum-silicon alloy (AlSi) or an aluminum-silicon-copper alloy (AlSiCu).

The drain electrode 54 is formed on the back surface 12 of the semiconductor substrate 10. The drain electrode 54 is formed of a conductive material such as metal.

As described above, the active portion 110 may have a trench MOSFET structure. An example of the method of manufacturing each component of the active portion 110 has been described, but the method of manufacturing the active portion 110 is not limited to the above method. The active portion 110 can be manufactured by a common method used by persons skilled in the art.

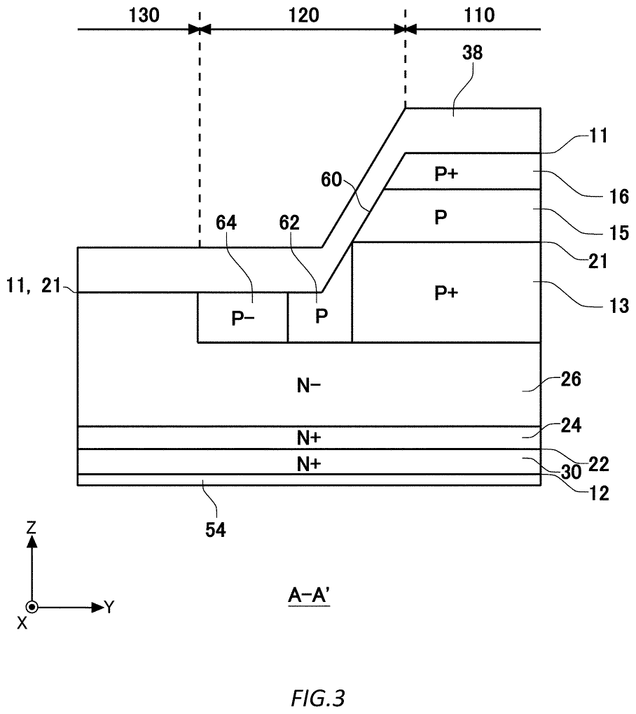

FIG. 3 illustrates an example of an A-A′ cross section of the silicon carbide semiconductor device 100 illustrated in FIG. 18. The pressure resistant structure portion 120 of this example has a step portion 60, an electric field relaxation region 62, and a junction termination region 64. That is, the pressure resistant structure portion 120 of this example has a junction termination structure.

The step portion 60 is provided on the outer periphery of the base region 15. The step portion 60 may be provided up to a position deeper than the bottom surface of the base region 15 in the depth direction of the semiconductor substrate 10. The step portion 60 may connect the front surface 11 of the semiconductor substrate 10 and the upper surface 21 of the epitaxial region 20. That is, in the pressure resistant structure portion 120 outside the end portion of the step portion 60 around the active portion 110 and the element isolation portion 130, the front surface 11 of the semiconductor substrate 10 and the upper surface 21 of the epitaxial region 20 may coincide with each other.

The electric field relaxation region 62 is a second conductivity type of region provided in contact with the first high concentration base region 13 in the vicinity of the end portion of the step portion 60 and provided on the upper side of the first drift region 26. The electric field relaxation region 62 is, for example, of P type. The electric field relaxation region 62 may be provided by implanting a P type dopant. The P type dopant is, for example, an aluminum atom. The doping concentration of the electric field relaxation region 62 may be lower than the doping concentration of the first high concentration base region 13.

The junction termination region 64 is a second conductivity type of region provided in contact with the electric field relaxation region 62 on the upper side of the first drift region 26. The junction termination region 64 is, for example, of P− type. The junction termination region 64 may be provided by implanting a P type dopant. The P type dopant is, for example, an aluminum atom. The doping concentration of the junction termination region 64 may be lower than the doping concentration of the electric field relaxation region 62.

By making the doping concentrations of the electric field relaxation region 62 and the junction termination region 64 lower than the doping concentration of the first high concentration base region 13, the withstand voltage of the silicon carbide semiconductor device 100 can be increased.

A boundary between the pressure resistant structure portion 120 and the element isolation portion 130 may be defined by an end portion of the structure of the pressure resistant structure portion 120. In the structure of the pressure resistant structure portion 120, the end portion of the structure provided on the outermost side with the active portion 110 as a center may be set as the boundary between the pressure resistant structure portion 120 and the element isolation portion 130. That is, the end portion of the junction termination region 64 may be a boundary between the pressure resistant structure portion 120 and the element isolation portion 130.

As described above, the pressure resistant structure portion 120 may have a junction termination structure. An example of the method of manufacturing each component of the pressure resistant structure portion 120 has been described, but the method of manufacturing the pressure resistant structure portion 120 is not limited to the above method. The pressure resistant structure portion 120 can be manufactured by a common method used by persons skilled in the art.

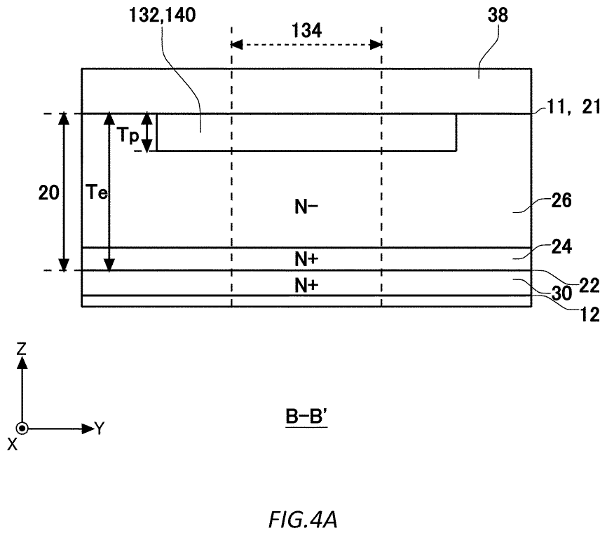

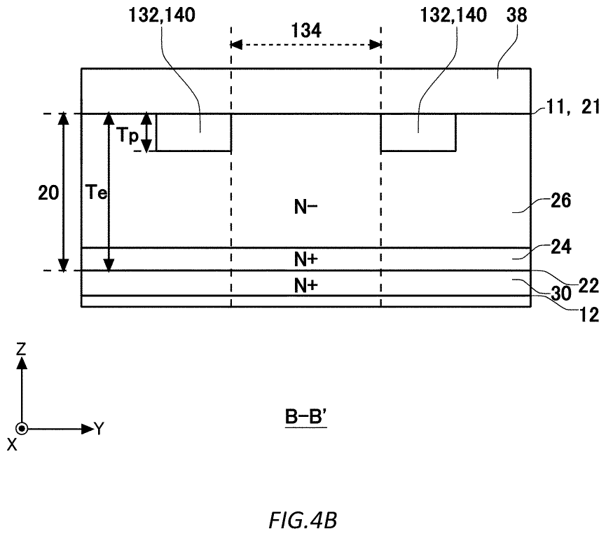

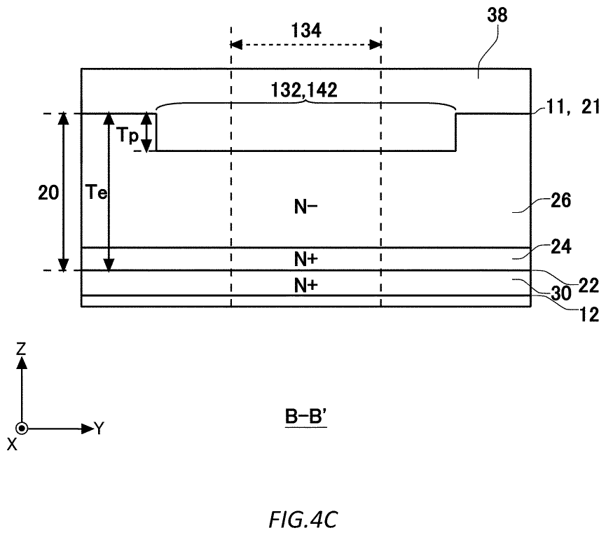

FIG. 4A illustrates an example of a B-B′ cross section of the silicon carbide semiconductor device 100 illustrated in FIG. 1B. The cross-sectional view of FIG. 4A is a cross-sectional view of a part of the element isolation portion 130. In the element isolation portion 130, the semiconductor substrate 10 has the epitaxial region 20 on the front surface 11 of the semiconductor substrate 10. That is, the front surface 11 of the semiconductor substrate 10 and the upper surface 21 of the epitaxial region 20 coincide with each other. The element isolation portion 130 includes an extension prevention portion 132 which is provided to elongate along each of two opposing end sides on the upper surface 21 of the epitaxial region 20 and prevents the extension of the interface dislocation of the semiconductor substrate 10.

The extension prevention portion 132 may have a thickness which is larger than 0 and is 50% or less of the thickness of the epitaxial region 20 in the depth direction of the semiconductor substrate 10. That is, a thickness Tp of the extension prevention portion 132 may be larger than 0 and 50% or less of a thickness Te of the epitaxial region 20. Further, the extension prevention portion 132 may have a thickness of 5 μm or less from the upper surface 21 of the epitaxial region 20 in the depth direction of the semiconductor substrate 10. That is, the thickness Tp of the extension prevention portion 132 may be 5 μm or less from the upper surface 21 of the epitaxial region 20. By making the thickness Tp of the extension prevention portion 132 thinner than the thickness Te of the epitaxial region 20, it is possible to reduce a possibility that the extension prevention portion 132 is provided to damage the semiconductor substrate 10.

The width of the extension prevention portion 132 may be wider than the width of the dicing region 134, and both ends of the dicing region 134 may be provided inside both ends of the extension prevention portion 132. Therefore, when the silicon carbide semiconductor device 100 in the wafer state is singulated, the extension prevention portion 132 may remain on the end side of the silicon carbide semiconductor device 100 in a chip state. The width of the dicing region is, for example, 100 μm.

By providing the extension prevention portion 132 in the (11-20) direction of the semiconductor substrate 10, it is possible to prevent the extension of the interface dislocation occurring in the middle of the manufacturing process of the silicon carbide semiconductor device 100. The interface dislocation occurring in the middle of the manufacturing process of the silicon carbide semiconductor device 100 extends in the (1-100) direction of the semiconductor substrate 10. The extension prevention portion 132 is provided in the (11-20) direction of the semiconductor substrate 10, so that the extension of the interface dislocation is stopped by the extension prevention portion 132 even when the interface dislocation occurs in the middle of the manufacturing process of the silicon carbide semiconductor device 100, and thus the number of silicon carbide semiconductor chips that become unusable due to the extension of the interface dislocation can be reduced. Details of a forming process of the interface dislocation in the middle of the manufacturing process of the silicon carbide semiconductor device 100 will be described later.

The extension prevention portion 132 may include an ion implantation region 140 which has a thickness in the depth direction of the semiconductor substrate 10, is provided to elongate along each of two opposing end sides on the upper surface 21 of the epitaxial region 20, and has crystal defects. In this example, the extension prevention portion 132 is the ion implantation region 140 having crystal defects. The ion implantation region 140 may be formed by ion implantation, may be formed by ion implantation with energy of 8 MeV or less, or may be formed by ion implantation of at least one of Al ions or P ions. An amount of crystal defects in the ion implantation region 140 may be 5×10¹³/cm² or more and 1×10¹⁶/cm² or less according to measurement by an electron spin resonance method.

Since the ion implantation region 140 has crystal defects, it is possible to prevent the extension of the interface dislocations extending in the (1-100) direction of the semiconductor substrate 10. Further, by forming the ion implantation region 140 by performing ion implantation with energy of 8 MeV or less, the thickness Tp of the extension prevention portion 132 can be made thinner than the thickness Te of the epitaxial region 20.

FIG. 4B illustrates a modification of the B-B′ cross section of the silicon carbide semiconductor device 100 illustrated in FIG. 1B. This example is different from the example of FIG. 4A in that two extension prevention portions 132 are provided apart from each other in the Y axis direction. Other features may be the same as in the example of FIG. 4A. That is, the extension prevention portion 132 may be the ion implantation region 140 having crystal defects.

The extension prevention portions 132 of this example are provided outside the dicing region 134 so as to be in contact with both ends of the dicing region 134, respectively. Also in this case, when the silicon carbide semiconductor device 100 in the wafer state is singulated, the extension prevention portion 132 may remain at the end side of the silicon carbide semiconductor device 100 in the chip state. That is, in any of the examples of FIGS. 4A and 4B, when the silicon carbide semiconductor device 100 in the wafer state is singulated, the silicon carbide semiconductor device 100a illustrated in FIG. 1C may be obtained.

FIG. 4C illustrates a modification of the B-B′ cross section of the silicon carbide semiconductor device 100 illustrated in FIG. 1B. In this example, one extension prevention portion 132 is provided continuously in the Y axis direction, but this example is different from the examples of FIGS. 4A and 4B in having a trench structure 142. Other features may be the same as in the examples of FIGS. 4A and 4B.

The extension prevention portion 132 may include the trench structure 142 which has a thickness in the depth direction of the semiconductor substrate 10 and is provided to elongate along each of two opposing end sides on the upper surface 21 of the epitaxial region 20. In this example, the extension prevention portion 132 is the trench structure 142. The inside of the trench structure 142 may be filled with the insulating film 38, but the present invention is not limited thereto.

The trench structure 142 of this example has a rectangular shape, but the shape of the trench structure 142 is not limited thereto. The shape of the trench structure 142 may be a tapered shape in which the width of the upper portion of the trench structure 142 is wider than the width of the lower portion, and the width gradually narrows from the upper portion to the lower portion. The shape of the trench structure 142 may be a reverse tapered shape in which the width of the upper portion of the trench structure 142 is narrower than the width of the lower portion, and the width gradually increases from the upper portion to the lower portion. In the trench structure 142 of this example, the lower surface in contact with the first drift region 26 is substantially flat, but the lower surface of the trench structure 142 may have a curved surface shape. That is, in the depth direction of the semiconductor substrate 10, the depth of the lower surface of the trench structure 142 may be constant, or may have a step or inclination.

One trench structure 142 of this example is provided continuously in the Y axis direction. As in the example of FIG. 4B, the trench structure 142 may be provided outside the dicing region 134 so as to be in contact with both ends of the dicing region 134.

By providing the trench structure 142, a step structure is formed on the upper surface 21 of the epitaxial region 20, and it is possible to prevent the extension of the interface dislocation extending in the (1-100) direction of the semiconductor substrate 10.

As described above, the silicon carbide semiconductor device 100 may have the extension prevention portion 132 in the element isolation portion 130, and the extension prevention portion 132 may include the ion implantation region 140 or the trench structure 142. In the examples of FIGS. 4A to 4C, a case is illustrated in which the extension prevention portion 132 is the ion implantation region 140 or the trench structure 142, but the extension prevention portion 132 may include both the ion implantation region 140 and the trench structure 142.

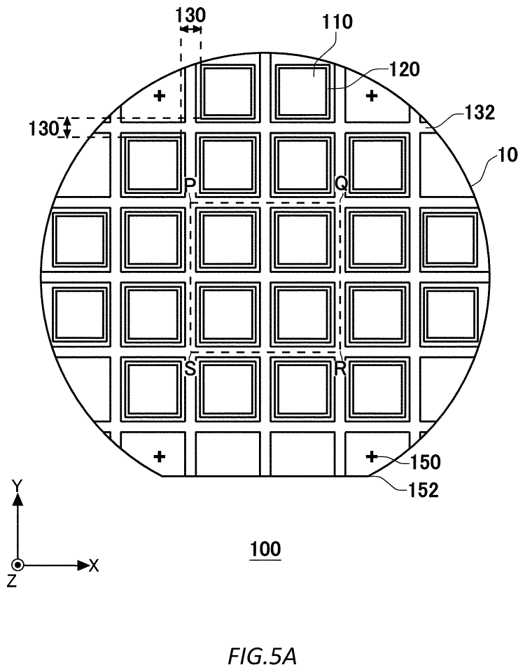

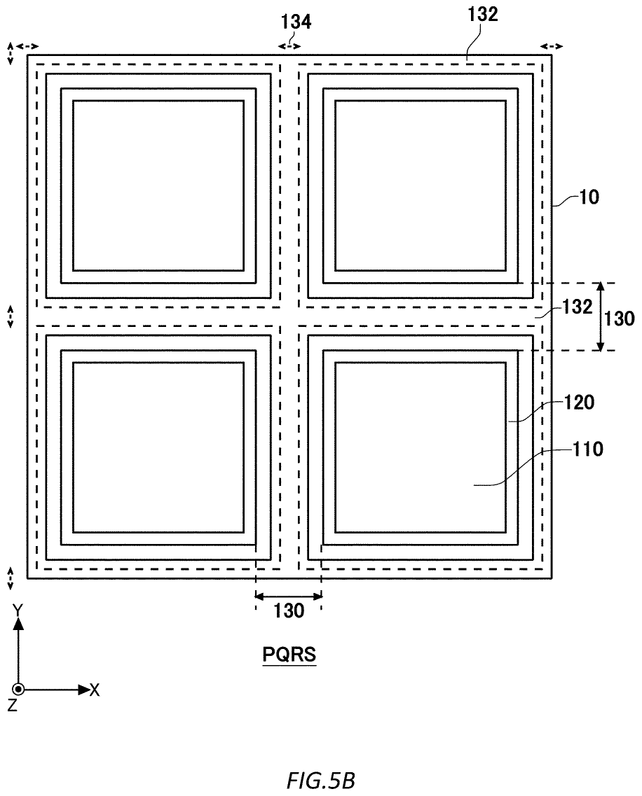

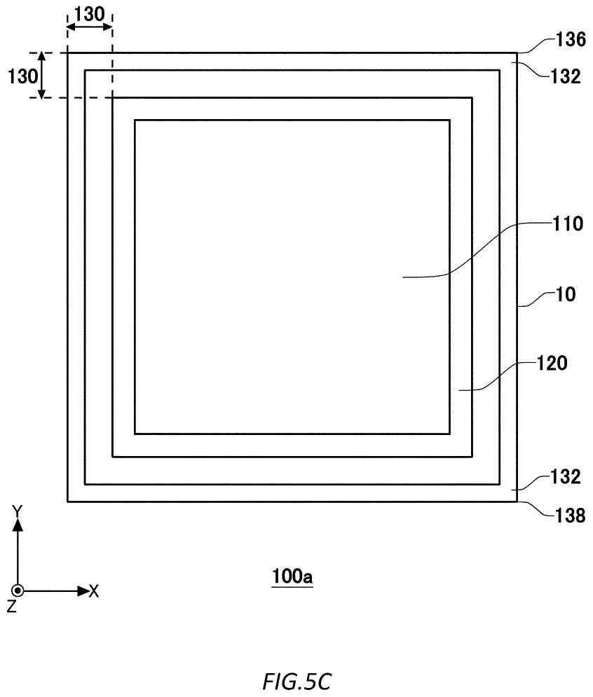

FIG. 5A illustrates a top view of a modification of the silicon carbide semiconductor device 100. The extension prevention portion 132 of this example is different from the example of FIG. 1A in that it is provided in the X axis direction and the Y axis direction. Other features may be the same as in the example of FIG. 1A.

The extension prevention portion 132 may be provided to elongate in the X axis direction and the Y axis direction. That is, the extension prevention portion 132 may be provided to elongate in the (11-20) direction and the (1-100) direction of the semiconductor substrate 10. Since the extension prevention portion 132 is provided to elongate in the (11-20) direction and the (1-100) direction of the semiconductor substrate 10, it is possible to improve a bias of a stress distribution in the semiconductor substrate 10 occurring during the manufacturing process of the silicon carbide semiconductor device 100 as compared with a case where the extension prevention portion 132 is provided to elongate only in the (11-20) direction of the semiconductor substrate 10, and it is possible to suppress a damage due to the stress. The width of the extension prevention portion 132 elongating in the (11-20) direction of the semiconductor substrate 10 and the width of the extension prevention portion 132 elongating in the (1-100) direction of the semiconductor substrate 10 may be substantially the same.

FIG. 5B illustrates an example of an enlarged view of a PQRS region of the silicon carbide semiconductor device 100 illustrated in FIG. 5A.

In either direction of the X axis and the Y axis, the width of the extension prevention portion 132 may be larger than the width of the dicing region 134, and both ends of the dicing region 134 may be inside both ends of the extension prevention portion 132. That is, the silicon carbide semiconductor device 100 may be singulated by dicing at least a part of extension prevention portion 132.

FIG. 5C illustrates a top view of a modification of the silicon carbide semiconductor chip 100a. The extension prevention portion 132 of this example is different from that of the example of FIG. 1C in that it is provided in the X axis direction and the Y axis direction. Other features may be the same as in the example of FIG. 1C.

The extension prevention portion 132 may be provided on four sides of the semiconductor substrate 10. That is, the extension prevention portion 132 may be provided in the (11-20) direction of the semiconductor substrate 10, or may be provided in the (1-100) direction of the semiconductor substrate 10. The extension prevention portion 132 may be provided to elongate from one end to the other end of the end side.

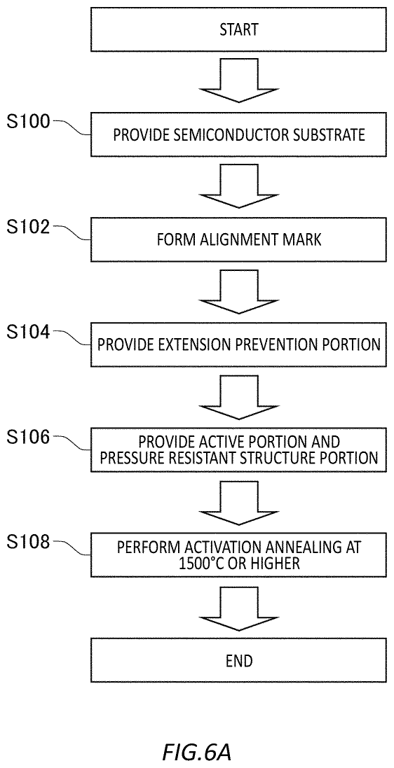

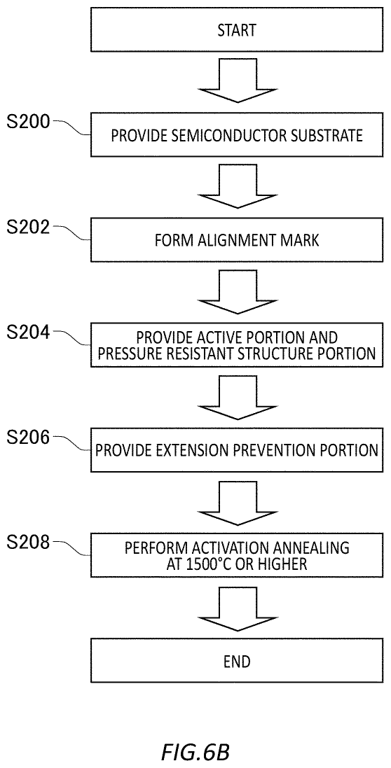

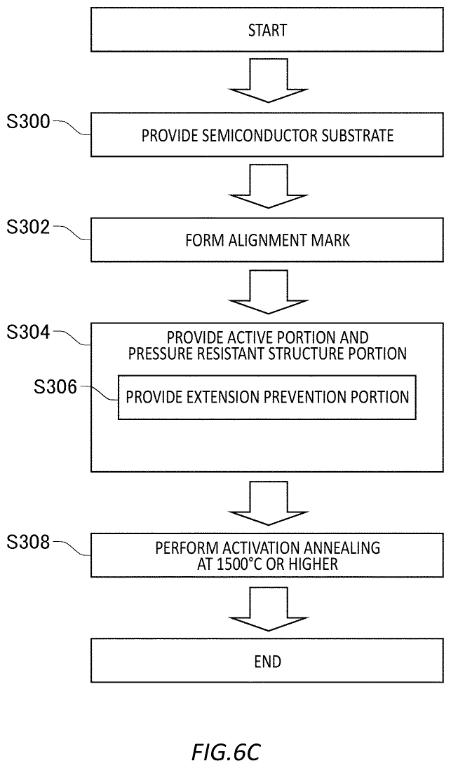

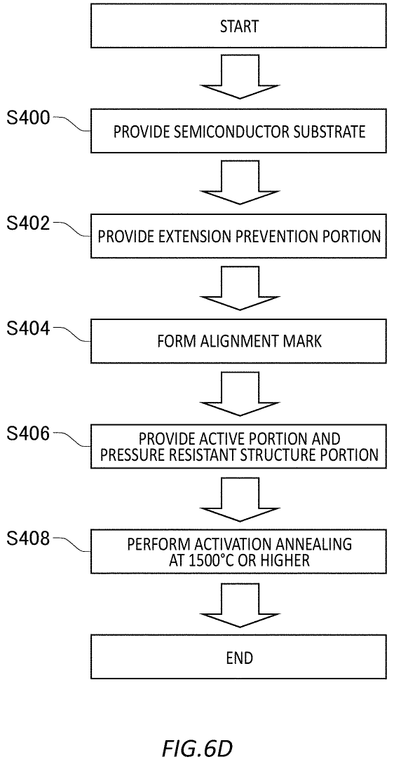

FIG. 6A illustrates an example of a flowchart of the manufacturing process of the silicon carbide semiconductor device 100. This example shows an example of the flowchart of the manufacturing process of the silicon carbide semiconductor device 100, and the present invention is not limited thereto.

In S100, the semiconductor substrate 10 made of silicon carbide is provided. The crystal structure of the semiconductor substrate 10 may be 4H—SiC, and the main surface of the semiconductor substrate 10 may be perpendicular to the (000-1) direction of the semiconductor substrate 10.

In S102, the alignment mark 150 is formed on the semiconductor substrate 10. A method of forming the alignment mark 150 is not particularly limited, and the alignment mark can be formed by a common method used by persons skilled in the art.

In S104, the extension prevention portion 132 that prevents extension of an interface dislocation is provided along each of two opposing end sides on the upper surface 21 of the epitaxial region 20 of the semiconductor substrate 10.

A step of providing the extension prevention portion 132 may include a step of providing the extension prevention portion 132 along the (11-20) direction of the semiconductor substrate 10. By providing the extension prevention portion 132 in the (11-20) direction of the semiconductor substrate 10, it is possible to prevent the extension of the interface dislocation occurring in the middle of the manufacturing process of the silicon carbide semiconductor device 100. The interface dislocation occurring in the middle of the manufacturing process of the silicon carbide semiconductor device 100 extends in the (1-100) direction of the semiconductor substrate 10. The extension prevention portion 132 is provided in the (11-20) direction of the semiconductor substrate 10, so that the extension of the interface dislocation is stopped by the extension prevention portion 132 even when the interface dislocation occurs in the middle of the manufacturing process of the silicon carbide semiconductor device 100, and thus the number of silicon carbide semiconductor chips that become unusable due to the extension of the interface dislocation can be reduced. Details of a forming process of the interface dislocation in the middle of the manufacturing process of the silicon carbide semiconductor device 100 will be described later.

The step of providing the extension prevention portion 132 may include a step of providing the extension prevention portion 132 along the (1-100) direction of the semiconductor substrate 10. Since the extension prevention portion 132 is provided to elongate in the (11-20) direction and the (1-100) direction of the semiconductor substrate 10, it is possible to improve a bias of a stress distribution in the semiconductor substrate 10 occurring during the manufacturing process of the silicon carbide semiconductor device 100 as compared with a case where the extension prevention portion 132 is provided to elongate only in the (11-20) direction of the semiconductor substrate 10, and it is possible to suppress a damage due to the stress.

The step of providing the extension prevention portion 132 may include a step of performing ion implantation on the element isolation portion 130. The step of performing ion implantation may include a step of performing ion implantation with energy of 8 MeV or less. Further, the step of performing ion implantation may include a step of performing ion implantation of at least one of Al ions and P ions. The ion implantation region 140 having crystal defects may be formed by the ion implantation. By providing the ion implantation region 140 having crystal defects, it is possible to prevent the extension of the interface dislocation extending in the (1-100) direction of the semiconductor substrate 10.

The step of providing the extension prevention portion 132 may include a step of forming the trench structure 142 which has a thickness in the depth direction of the semiconductor substrate 10 and elongates along each of two opposing end sides on the upper surface 21 of the epitaxial region 20. By providing the trench structure 142, a step structure is formed on the upper surface 21 of the epitaxial region 20, and it is possible to prevent the extension of the interface dislocation extending in the (1-100) direction of the semiconductor substrate 10.

The step (S102) of forming the alignment mark 150 on the semiconductor substrate 10 may be before the step (S104) of providing the extension prevention portion 132, but the present invention is not limited thereto. By forming the extension prevention portion 132 after forming the alignment mark 150, it is possible to perform accurate alignment on the extension prevention portion 132.

In S106, the active portion 110 is provided on the semiconductor substrate 10. Further, the pressure resistant structure portion 120 is provided on the outer periphery of the active portion 110. The active portion 110 may have a MOSFET structure, and the pressure resistant structure portion 120 may have a junction termination structure, but the present invention is not limited thereto. The active portion 110 and the pressure resistant structure portion 120 can be manufactured by a common method used by persons skilled in the art.

The element isolation portion 130 is provided on the outer periphery of the pressure resistant structure portion 120. The step of providing the element isolation portion 130 may be a step of providing the active portion 110 and/or the pressure resistant structure portion 120. That is, the element isolation portion 130 may be a region in the semiconductor substrate 10 other than a region where the active portion 110 and the pressure resistant structure portion 120 are provided, and the element isolation portion 130 which is a region other than the region where the active portion 110 and the pressure resistant structure portion 120 are provided may be provided by providing the active portion 110 and the pressure resistant structure portion 120 on the semiconductor substrate 10.

The step of providing the extension prevention portion 132, which prevents the extension of the interface dislocation, along each of two opposing end sides on the upper surface 21 of the epitaxial region 20 of the semiconductor substrate 10 may be a step of providing, in the element isolation portion 130, the extension prevention portion 132, which prevents the extension of the interface dislocation, along each of two opposing end sides on the upper surface 21 of the epitaxial region 20 of the semiconductor substrate 10. A configuration in which the extension prevention portion 132 is provided in the element isolation portion 130 is not limited to that manufactured in the order of providing the element isolation portion 130 and then providing the extension prevention portion 132. A configuration in which the element isolation portion 130 is provided in a region including the extension prevention portion 132 after the extension prevention portion 132 is provided is also included the configuration in which the extension prevention portion 132 is provided in the element isolation portion 130.

In S108, the semiconductor substrate is subjected to activation annealing after the step (S104) of providing the extension prevention portion 132. The step of performing activation annealing may include a step of first performing activation annealing of the semiconductor substrate 10 at 1500° C. or higher after the step (S100) of providing the semiconductor substrate 10. The manufacturing process of the silicon carbide semiconductor device 100 may include a plurality of annealing treatments for immobilizing ions implanted into the semiconductor substrate 10. The manufacturing process of the silicon carbide semiconductor device 100 may include a step of performing annealing even before the step (S104) of providing extension prevention portion 132. In this case, the annealing temperature of the annealing treatment performed before the step (S104) of providing the extension prevention portion 132 is preferably lower than 1500° C. That is, the step of performing activation annealing of the semiconductor substrate 10 at 1500° C. or higher is preferably performed first after the step (S104) of providing the extension prevention portion 132.

The interface dislocation occurring in the middle of the manufacturing process of the silicon carbide semiconductor device 100 becomes in a movable state when the semiconductor substrate 10 is heated to a high temperature. In a case where the interface dislocation is in the movable state, when stress is applied to the semiconductor substrate 10, the interface dislocation extends in the (1-100) direction of the semiconductor substrate 10. Therefore, by providing the extension prevention portion 132 before the step of performing activation annealing of the semiconductor substrate 10 at 1500° C. or higher, even when the interface dislocation having become in the movable state extends, the extension prevention portion 132 can prevent the extension of the interface dislocation. Accordingly, it is possible to reduce the number of silicon carbide semiconductor chips which become unusable due to the extension of the interface dislocation. Details of a forming process of the interface dislocation in the middle of the manufacturing process of the silicon carbide semiconductor device 100 will be described later.

FIG. 6B illustrates a modification of the flowchart of the manufacturing process of the silicon carbide semiconductor device 100. The flowchart of this example is different from that of the example of FIG. 6A in including a step (S206) of providing the extension prevention portion 132 after the step (S204) of providing the active portion 110 and the pressure resistant structure portion 120. Other features may be the same as in the example of FIG. 6A. That is, a step (S208) of performing activation annealing of the semiconductor substrate 10 may be included after the step (S206) of providing the extension prevention portion 132, and the step (S208) of performing activation annealing may include a step of first performing activation annealing of the semiconductor substrate 10 at 1500° C. or higher after the step (S200) of providing the semiconductor substrate 10. By providing the extension prevention portion 132 before the step of performing activation annealing of the semiconductor substrate 10 at 1500° C. or higher, even when the interface dislocation having become in the movable state extends, the extension prevention portion 132 can prevent the extension of the interface dislocation.

FIG. 6C illustrates a modification of the flowchart of the manufacturing process of the silicon carbide semiconductor device 100. The flowchart of this example is different from the examples of FIGS. 6A and 6B in including a step (S306) of providing the extension prevention portion 132 in the middle of the step (S304) of providing the active portion 110 and the pressure resistant structure portion 120. Other features may be the same as in the examples of FIGS. 6A and 6B. That is, a step (S308) of performing activation annealing of the semiconductor substrate 10 may be included after the step (S306) of providing the extension prevention portion 132, and the step (S308) of performing activation annealing may include a step of first performing activation annealing of the semiconductor substrate 10 at 1500° C. or higher after the step (S300) of providing the semiconductor substrate 10. By providing the extension prevention portion 132 before the step of performing activation annealing of the semiconductor substrate 10 at 1500° C. or higher, even when the interface dislocation having become in the movable state extends, the extension prevention portion 132 can prevent the extension of the interface dislocation.

The step (S306) of providing the extension prevention portion 132 may be performed in the middle of the step (S304) of providing the active portion 110 and the pressure resistant structure portion 120. That is, the step (S306) of providing the extension prevention portion 132 may be performed before or after the step of providing the second drift region 28, may be performed before or after the step of providing the first high concentration base region 13, may be performed before or after the step of providing the second high concentration base region 14, may be performed before or after the step of providing the base region 15, may be performed before or after the step of providing the contact region 16, or may be performed before or after the step of providing the source region 18.

FIG. 6D illustrates a modification of the flowchart of the manufacturing process of the silicon carbide semiconductor device 100. The flowchart of this example is different from those of the examples of FIGS. 6A to 6C in including a step (S402) of providing the extension prevention portion 132 before the step (S404) of forming the alignment mark. Other features may be the same as in the examples of FIGS. 6A to 6C. That is, a step (S408) of performing activation annealing of the semiconductor substrate 10 may be included after the step (S402) of providing the extension prevention portion 132, and the step (S408) of performing activation annealing may include a step of first performing activation annealing of the semiconductor substrate 10 at 1500° C. or higher after the step (S400) of providing the semiconductor substrate 10. By providing the extension prevention portion 132 before the step of performing activation annealing of the semiconductor substrate 10 at 1500° C. or higher, even when the interface dislocation having become in the movable state extends, the extension prevention portion 132 can prevent the extension of the interface dislocation.

When the extension prevention portion 132 is provided (S402) before the step (S404) of forming the alignment mark, alignment for forming the extension prevention portion 132 may be performed by using the orientation flat 152 of the semiconductor substrate 10.

As described above, a method of manufacturing the silicon carbide semiconductor device 100 of the present application includes a step of providing the extension prevention portion 132. The order of the step of providing the extension prevention portions 132 can be freely changed. The step of providing the extension prevention portion 132 may be before the step of first performing activation annealing of the semiconductor substrate 10 at 1500° C. or higher. By providing the extension prevention portion 132 before the step of performing activation annealing of the semiconductor substrate 10 at 1500° C. or higher, even when the interface dislocation having become in the movable state extends, the extension prevention portion 132 can prevent the extension of the interface dislocation.

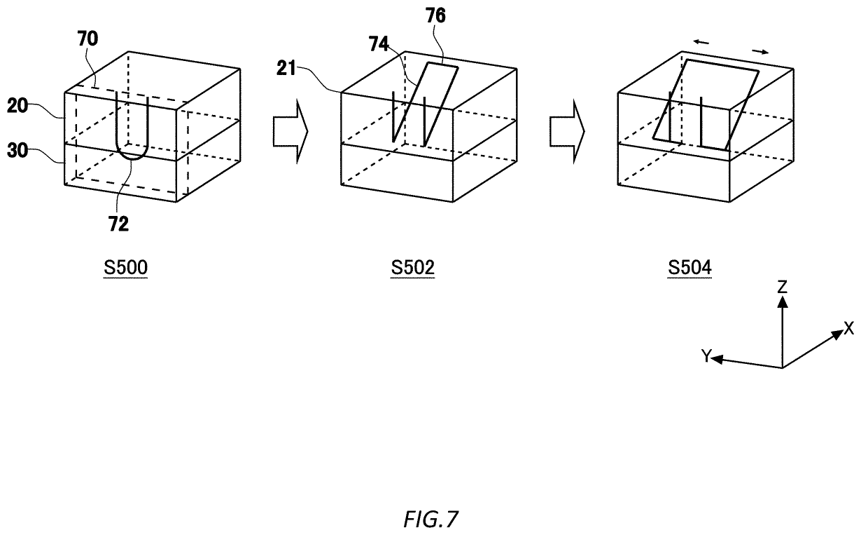

FIG. 7 illustrates an example of a forming process of the interface dislocation 76. In S500, a basal plane dislocation 72 is formed on a basal plane 70 in a process of forming the epitaxial region 20 on the upper side of the basal region 30 by epitaxial growth. In S502, when the semiconductor substrate 10 is subjected to a high temperature treatment of 1500° C. or higher, the basal plane dislocation 72 becomes in the movable state, both ends of the basal plane dislocation 72 are converted into threading edge dislocations 74 to be fixed, the basal plane dislocation slides in the epitaxial region 20 and stop near the upper surface 21 of the epitaxial region 20, and the interface dislocation 76 is formed. Thereafter, in S504, stress is applied to the semiconductor substrate 10, so that the interface dislocation 76 extends in the (1-100) direction of the semiconductor substrate 10. In the silicon carbide semiconductor device 100 in the wafer state, the interface dislocation 76 may extend over a length of three chips or more and five chips or less in a singulated silicon carbide semiconductor chip size.

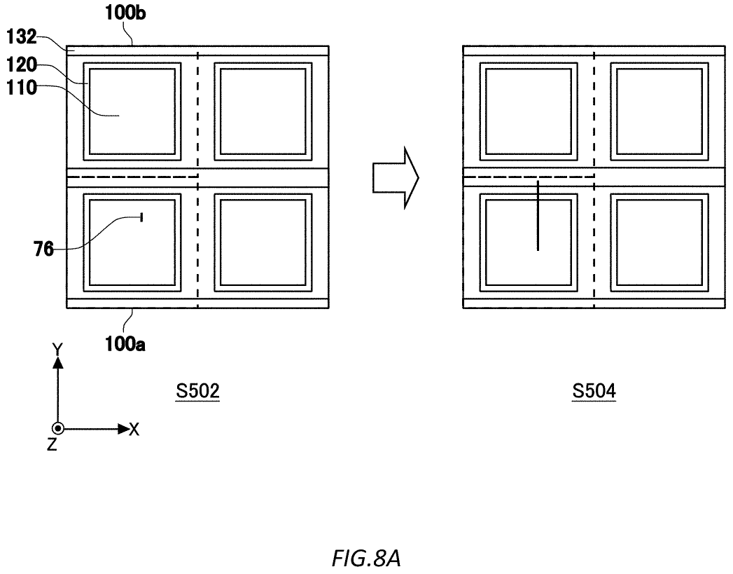

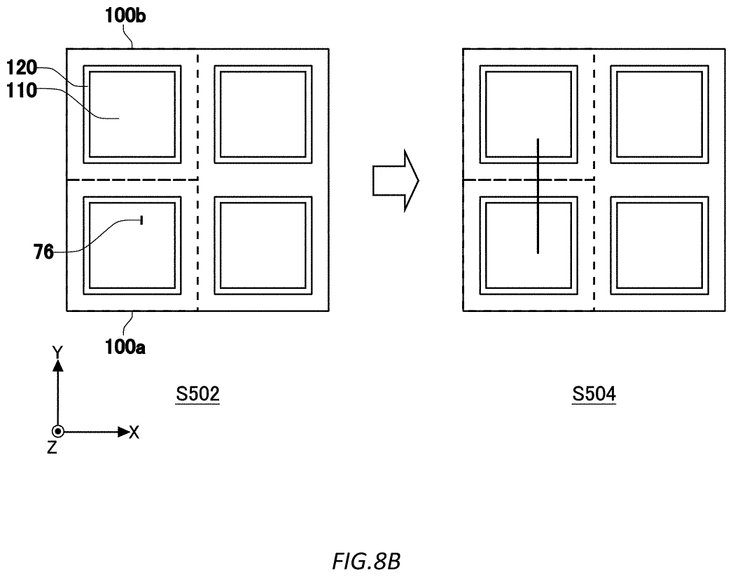

FIG. 8A illustrates an example of a process of preventing the extension of the interface dislocation 76 in the silicon carbide semiconductor device 100. In S502, the interface dislocation 76 is formed near the upper surface 21 of the epitaxial region 20. In this example, an example is shown in which the interface dislocation 76 is formed in a region, which becomes the silicon carbide semiconductor chip 100a when singulated, in the silicon carbide semiconductor device 100 in a wafer state. When the interface dislocation 76 extends in S504, the extension prevention portion 132 provided at a boundary between the silicon carbide semiconductor chip 100a and a silicon carbide semiconductor chip 100b prevents the extension of the interface dislocation 76. Therefore, in the silicon carbide semiconductor device 100 of this example, the extension prevention portion 132 elongating in the (11-20) direction which is a direction perpendicular to the (1-100) direction of the semiconductor substrate 10 which is the extension direction of the interface dislocation 76 is provided to prevent the extension of the interface dislocation 76 and disturb the interface dislocation 76 from extending to the silicon carbide semiconductor chip 100b, and thus it is possible to reduce the number of silicon carbide semiconductor chips which become unusable due to the extension of the interface dislocation 76.

FIG. 8B illustrates an example of a forming process of the interface dislocation 76 in a silicon carbide semiconductor device according to a comparative example. On the silicon carbide semiconductor device according to the comparative example, the extension prevention portion 132 is not provided, so that the extension of the interface dislocation 76 cannot be prevented, and the silicon carbide semiconductor chip 100b may become unusable due to the extension of the interface dislocation 76.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that the embodiments to which such alterations or improvements are made can be included in the technical scope of the present invention.

The operations, procedures, steps, and stages of each process performed by a device, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10: semiconductor substrate; 11: front surface of semiconductor substrate 10; 12: back surface of semiconductor substrate 10; 13: first high concentration base region; 14: second high concentration base region; 15: base region; 16: contact region; 18: source region; 20: epitaxial region; 21: upper surface of epitaxial region 20; 22: lower surface of epitaxial region 20; 24: buffer region; 26: first drift region; 28: second drift region; 30: basal region; 38: insulating film; 40: gate trench portion; 42: gate insulating film; 44: gate conductive portion; 50: barrier metal; 52: source electrode; 54: drain electrode; 60: step portion; 62: electric field relaxation region; 64: junction termination region; 70: basal plane; 72: basal plane dislocation; 74: threading edge dislocation; 76: interface dislocation; 100: silicon carbide semiconductor device; 110: active portion; 120: pressure resistant structure portion; 130: element isolation portion; 132: extension prevention portion; 134: dicing region; 136: first end side; 138: second end side; 140: ion implantation region; 142: trench structure; 150: alignment mark; and 152: orientation flat.

What is claimed is:

1. A silicon carbide semiconductor device which includes a semiconductor substrate made of silicon carbide and having an epitaxial region on a front surface, the silicon carbide semiconductor device comprising:
an active portion which is provided on the semiconductor substrate;
a pressure resistant structure portion which is provided on an outer periphery of the active portion on the semiconductor substrate; and
an element isolation portion which is provided on an outer periphery of the pressure resistant structure portion on the semiconductor substrate, wherein
the element isolation portion includes an extension prevention portion which is provided to elongate along each of two opposing end sides on an upper surface of the epitaxial region and prevents extension of interface dislocation of the semiconductor substrate.

2. The silicon carbide semiconductor device according to claim 1, wherein the extension prevention portion includes an ion implantation region which has a thickness in a depth direction of the semiconductor substrate, is provided to elongate along each of the two opposing end sides on the upper surface of the epitaxial region, and has crystal defects.

3. The silicon carbide semiconductor device according to claim 2, wherein an amount of the crystal defects in the ion implantation region is 5×10¹³/cm² or more and 1×10¹⁶/cm² or less.

4. The silicon carbide semiconductor device according to claim 1, wherein the extension prevention portion includes a trench structure which has a thickness in a depth direction of the semiconductor substrate and is provided to elongate along each of the two opposing end sides on the upper surface of the epitaxial region.

5. The silicon carbide semiconductor device according to claim 1, wherein the extension prevention portion has a thickness which is larger than 0 and is 50% or less of a thickness of the epitaxial region in a depth direction of the semiconductor substrate.

6. The silicon carbide semiconductor device according to claim 5, wherein the extension prevention portion has a thickness of 5 μm or less from the upper surface of the epitaxial region in the depth direction of the semiconductor substrate.

7. The silicon carbide semiconductor device according to claim 1, wherein an elongation direction of the extension prevention portion is a (11-20) direction of the semiconductor substrate.

8. The silicon carbide semiconductor device according to claim 2, wherein an elongation direction of the extension prevention portion is a (11-20) direction of the semiconductor substrate.

9. The silicon carbide semiconductor device according to claim 1, wherein the extension prevention portion is provided to elongate from one end to another end of the end side.

10. The silicon carbide semiconductor device according to claim 1, wherein the extension prevention portion is provided on four sides of the semiconductor substrate.

11. A method of manufacturing a silicon carbide semiconductor device comprising:
providing a semiconductor substrate made of silicon carbide;
providing an active portion on the semiconductor substrate;
providing a pressure resistant structure portion on an outer periphery of the active portion;
providing an element isolation portion on an outer periphery of the pressure resistant structure portion; and
providing, in the element isolation portion, an extension prevention portion, which prevents extension of interface dislocation, along each of two opposing end sides on an upper surface of an epitaxial region of the semiconductor substrate.

12. The method of manufacturing the silicon carbide semiconductor device according to claim 11, comprising performing activation annealing of the semiconductor substrate after the providing the extension prevention portion.

13. The method of manufacturing the silicon carbide semiconductor device according to claim 12, wherein the performing activation annealing includes first performing activation annealing of the semiconductor substrate at 1500° C. or higher after the providing the semiconductor substrate.

14. The method of manufacturing the silicon carbide semiconductor device according to claim 11, comprising forming an alignment mark on the semiconductor substrate before the providing the extension prevention portion.

15. The method of manufacturing the silicon carbide semiconductor device according to claim 11, wherein the providing the extension prevention portion includes providing the extension prevention portion along a (11-20) direction of the semiconductor substrate.

16. The method of manufacturing the silicon carbide semiconductor device according to claim 15, wherein the providing the extension prevention portion includes providing the extension prevention portion along a (1-100) direction of the semiconductor substrate.

17. The method of manufacturing the silicon carbide semiconductor device according to claim 11, wherein the providing the extension prevention portion includes performing ion implantation into the element isolation portion.

18. The method of manufacturing the silicon carbide semiconductor device according to claim 17, wherein the performing ion implantation includes performing ion implantation with energy of 8 MeV or less.

19. The method of manufacturing the silicon carbide semiconductor device according to claim 18, wherein the performing ion implantation includes performing ion implantation of at least one of Al ions and P ions.

20. The method of manufacturing the silicon carbide semiconductor device according to claim 11, wherein the providing the extension prevention portion includes forming a trench structure which has a thickness in a depth direction of the semiconductor substrate and elongates along each of the two opposing end sides on the upper surface of the epitaxial region.
